(19) United States
(12) Patent Application Publication
(10) Pub. No.: US 2019/0079568 A1
(43) Pub. Date: Mar. 14, 2019

(54) HEAT EXCHANGE DEVICE AND EQUIPMENT SYSTEM HAVING HEAT EXCHANGE ABILITY

(71) Applicant: Casing Macron Technology Co., Ltd, New Taipei City (TW)

(72) Inventor: Yi-Chang Hsiao, New Taipei City (TW)

(21) Appl. No.: 16/118,870

(22) Filed: Aug. 31, 2018

(30) Foreign Application Priority Data
Sep. 11, 2017 (TW) 106213498
Jun. 7, 2018 (CN) 201820879998.0
Jun. 7, 2018 (CN) 201820880011.7

(51) Int. Cl. G06F 1/20; F25B 1/00; H05K 7/20

(52) U.S. Cl. CPC G06F 1/206; F25B 1/00; H05K 7/20145; H05K 7/20154; H05K 7/20381; G06F 2200/201; H05K 7/20172; G06F 1/20; H05K 7/20354; H05K 7/20327; H05K 7/20263; H05K 7/20209

(57) ABSTRACT

A heat exchange device and an equipment system using the same are illustrated. A pipe unit is filled with a heat-transfer medium, and via cycling of a vapor/gas pressurizer, a heat dissipation device and a throttling device, the heat-transfer medium flows to a heat sink having a heat sinking surface, and the heat sinking surface contacts a heat source, such that the heat-transfer medium flowing to the heat sink passes the heat sinking surface to take away the heat of the heat source. The heat exchange device is disposed in an equipment having at least a power supply and at least a working unit, wherein the working unit forms a heat source when operating, and the working unit contacts the heat sinking surface, such that a direct heat absorption and an efficient heat cycle are performed to achieve a heat dissipation effect.

### BACKGROUND

### 1. Technical Field

The present disclosure relates to a heat exchange device and an equipment system having the heat exchange device, for example, a host computer with heat dissipation ability, and the application of the equipment system having the heat exchange device is not limited to the host computer.

### 2. Description of Related Art

A conventional heat dissipation system, such as the heat dissipation system installed in a computer for heat sources of a central processing unit (CPU) and other chips, usually has fins disposed on the heat sources for dissipating and conducting heat. By leading the heat out from the heat sources via the fins, a heat dissipation process can be carried out. However, as the technology advances, contacting areas of the heat sources decrease, and computation speeds of chips increase, such that temperatures of heat sources extremely increase. If merely the fins are used for heat dissipation, heat dissipation efficiency may be poor. Further, a case of the computer is semi-closed, being hard to dissipate the heat, and after the computer is used for a long time, dust may be accumulated in the case of the computer, which decreases the heat dissipation efficiency. Thus, many manufacturers and researchers try to improve the conventional heat dissipation systems.

There are two general heat dissipation manners provided and developed by the manufacturers. One of the general heat dissipation manners is illustrated in FIG. 1, which adopts a liquid cooling system 40. The liquid cooling system 40 is directly connected to a central processing unit 51 of a host computer 50, and after a pipe system 41 inputs liquid with a low temperature from the liquid cooling system 40 to a heat conduction portion 42 which contacts the central processing unit 51, the liquid absorbs the heat generated by the central processing unit 51, and the temperature of the liquid increases. Then, the liquid flows to a heat dissipation terminal 43 via the pipe system 41, and a heat dissipation fan 44 is used to dissipate the heat of the liquid in the heat dissipation terminal 43 to decrease the temperature of the liquid. Next, via the pipe system 41, the liquid is sent to the liquid cooling system 40 and the heat conduction portion 42 again, so as to form an inner cycle and dissipate the heat of the central processing unit 51.

However, regarding cooling mechanism of the liquid cooling system 40, the flowing cycle is limited by an inner space of the host computer 50. Usually, a flowing distance is very short, and a flowing path is fixed, such that not only an installation location is limited, but also the liquid in the heat dissipation terminal 43 cannot efficiently dissipate the heat due to the too short cycle. Under a long-term usage, the liquid flowing into the heat conduction portion 42 may gradually increase its temperature, and thus the liquid cannot efficiently dissipate the heat of the central processing unit 51 anymore.

Another one of the general heat dissipation manners is illustrated in FIG. 2, which adopts a cooling fan system. In a host device 60, heat dissipation fans 44 are respectively disposed on a central processing unit 51 and a graphics processing unit (GPU) 62, and meanwhile, an exhausting fan 64 is disposed on the host device 60. By using the heat dissipation fans 44, the heat generated by the central processing unit 51 and graphics processing unit 62 can be lead out form the central processing unit 51 and graphics processing unit 62, and by using the exhausting fan 64 the led out heat can further be exhausted outside the host device 60, such that a heat exhaustion effect can be achieved.

The heat dissipation mechanism which adopts the heat dissipation fan 44 and the exhausting fan 64 can have the nice heat dissipation effect, but the heat dissipation fan 44 and the exhausting fan 64 must work when the host device 60 is turned on, which causes much electricity consumption. Further, noise may be induced due to running of the heat dissipation fan 44 and the exhausting fan 64. After a long-term usage, the temperatures of the central processing unit 51 and the graphics processing unit 62 increase, and though the heat dissipation fans 44 can generate air flow to take out the heat, the heat dissipation fans 44 disposed on the central processing unit 51 and the graphics processing unit 62 still cannot directly and efficiently dissipate heat of peripheral computing chips. Thus, whole heat dissipation efficiency should be further improved.

### SUMMARY

Since the above-mentioned conventional heat dissipation manners still have defects and disadvantages in practice, the Applicant diligently improves and modifies the conventional heat dissipation manners according to learned knowledge and practical experiences, and then provides a heat exchange device and an equipment system using the same in the present disclosure.

An objective of the present disclosure is used to provide a heat exchange device and an equipment system using the same, for quickly and efficiently decreasing the temperature in an equipment of the equipment system. The heat exchange device comprises a pipe unit, a vapor/gas pressurizer, a heat dissipation device, a throttling device, a heat sink, a control unit and a case. The pipe unit is filled with a heat-transfer medium. The vapor/gas pressurizer is connected to the pipe unit. The heat dissipation device is connected to the vapor/gas pressurizer via the pipe unit. The throttling device is connected to the heat dissipation device via the pipe unit. The heat sink is connected to the throttling device and the vapor/gas pressurizer via the pipe unit, and has a heat sinking surface. The control unit is electrically connected and signaling to the vapor/gas pressurizer, the heat dissipation device, the throttling device and the heat sink.

According to the heat exchange device, wherein the heat exchange device further comprises a case, the vapor/gas pressurizer, the heat dissipation device, the throttling device and the control unit are disposed inside the case, and the heat sink is disposed outside the case.

According to the heat exchange device, wherein the heat dissipation device comprises a heat dissipation fin bank, a fan or a water cooling heat dissipation device.

According to the heat exchange device, wherein the throttling device is a capillary, a temperature-sensitive expansion valve, an electronic expansion valve or an oriface.

The equipment system having heat exchange ability comprises an equipment and the heat exchange device as mentioned above, wherein the equipment further has at least a working unit therein, and the heat sink contacts the working unit.

In another embodiment, the equipment system having heat exchange ability comprises an equipment and a heat exchange device. The heat exchange device comprises a pipe unit, a vapor/gas pressurizer, a heat dissipation device, a throttling device, heat sinks and a control unit. The pipe unit is filled with a heat-transfer medium. The vapor/gas pressurizer is connected to the pipe unit. The heat dissipation device is connected to the vapor/gas pressurizer via the pipe unit. The throttling device is connected to the heat dissipation device via the pipe unit. The heat sink is connected to the throttling device and the vapor/gas pressurizer via the pipe unit, and each of the heat sinks has a heat sinking surface. The control unit is electrically connected and signaling to the vapor/gas pressurizer, the heat dissipation device, the throttling device and the heat sink. At least one working unit is disposed inside the equipment, and the heat sinking surface contacts the working unit.

According to the equipment system, wherein the heat sinks are connected via the pipe unit.

According to the equipment system, wherein the heat sinks are connected via the pipe unit in a serial connection manner.

According to the equipment system, wherein the heat sinks are sequentially connected via the pipe unit.

According to the equipment system, wherein the working units have chips, and the heat sinking surface contacts the chip.

According to the equipment system, wherein the heat sinking surfaces contact the corresponding chip.

According to the equipment system, wherein each of the heat sinking surfaces contacts the corresponding chip.

According to the equipment system, wherein the chip is a central processing unit or a graphics processing unit.

According to the equipment system, wherein the equipment further comprises a power supply disposed therein, and the power supply is electrically connected to the working unit.

According to the equipment system, wherein the power supply is electrically connected to the heat exchange device.

According to the equipment system, wherein the working unit further has a temperature sensor disposed between the heat sinking surface and the working unit, and the temperature sensor contact the heat sink and the working unit.

According to the equipment system, wherein the working unit further has a pulse width modulation gearing device, and the control unit is electrically connected and signaling to the pulse width modulation gearing device.

Regarding the heat exchange device and the equipment system using the same provided by the present disclosure, the heat sink of the heat exchange device can contact a heat source directly, such that effects of directly dissipating heat and decreasing a temperature can be performed, and a cooling effect is enhanced. Further, after the heat-transfer medium is cycled, the heat-transfer medium at the heat sink can maintain a low temperature state, and even after a long-term usage, the effect of decreasing the temperature cannot be getting poor. Meanwhile, in the equipment system having the heat exchange device, the working unit can directly contact the heat sink, thus having an efficient direct heat dissipation effect. Further, the heat exchange device can be in installed in the equipment without increasing the volume, Since the heat sink provides the direct and continuous heat dissipation effect, the operation temperature of the working unit is kept in a proper temperature range, thus preventing the delay and damage caused by the overheat.

### BRIEF DESCRIPTION OF THE DRAWINGS

The accompanying drawings are included to provide a further understanding of the present disclosure, and are incorporated in and constitute a part of this specification. The drawings illustrate exemplary embodiments of the present disclosure and, together with the description, serve to explain the principles of the present disclosure.

FIG. 1 is a schematic diagram of a conventional liquid cooling system.

FIG. 2 is a schematic diagram of a conventional cooling fan system.

FIG. 3 is a three-dimensional view of a heat exchange device according to a first embodiment of the present disclosure.

FIG. 4 is a three-dimensional explosive diagram of an equipment system which has the heat exchange device of the first embodiment.

FIG. 5 is a block diagram of another equipment system which has the heat exchange device of the first embodiment.

FIG. 6 is a three-dimensional diagram of the equipment system of FIG. 5.

FIG. 7 is a schematic diagram showing a whole structure configuration of a heat exchange device according to a second embodiment of the present disclosure.

FIG. 8 is a three-dimensional explosive diagram of an equipment system which has the heat exchange device of the second embodiment.

FIG. 9 is a schematic diagram showing a whole structure configuration of the equipment system of FIG. 8.

FIG. 10 is a block diagram of another equipment system which has the heat exchange device of the second embodiment.

FIG. 11 is a three-dimensional view of a heat exchange device according to a third embodiment of the present disclosure.

FIG. 12 is a schematic diagram showing a whole structure configuration of the heat exchange device of FIG. 11.

FIG. 13 is a block diagram of the heat exchange device of FIG. 11.

FIG. 14 is a three-dimensional explosive diagram of an equipment system which has the heat exchange device of the third embodiment.

FIG. 15 is another three-dimensional explosive diagram of the equipment system which has the heat exchange device of the third embodiment.

FIG. 16 is a three-dimensional diagram of the equipment system which has the heat exchange device of the third embodiment.

FIG. 17 is a schematic diagram showing operation of the equipment system which has the heat exchange device of the third embodiment.

### DESCRIPTION OF THE EXEMPLARY EMBODIMENTS

To understand the technical features, content and advantages of the present disclosure and its efficacy, the present disclosure will be described in detail with reference to the accompanying drawings. The drawings are for illustrative and auxiliary purposes only and may not necessarily be the true scale and precise configuration of the present disclosure. Therefore, the scope of the present disclosure should not be limited to the scale and configuration of the attached drawings.

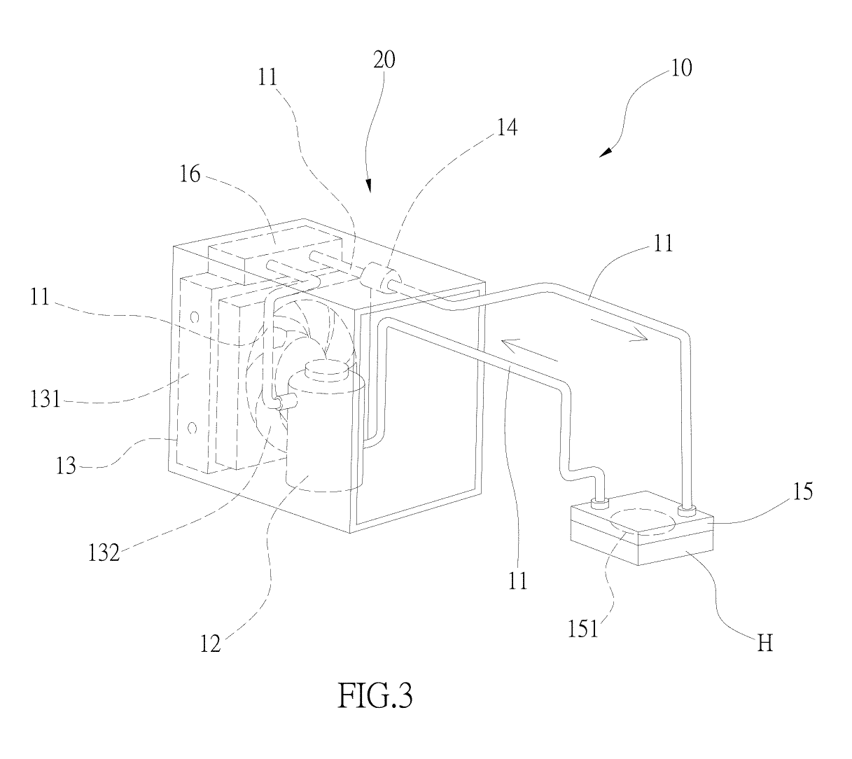

Referring to FIG. 3, which is a three-dimensional view of a heat exchange device according to a first embodiment of the present disclosure, the heat exchange device has heat exchange ability, and thus heat can be sent to a cool end from a heat end. The heat exchange device 10 comprises a pipe unit 11, a vapor/gas pressurizer 12, a heat dissipation device 13, a throttling device 14, a heat sink 15, a control unit 16 and a case 20.

The pipe unit 11 is filled with heat-transfer medium (not shown in the drawings), and the heat-transfer medium is material which is able to be changed between a gas state and liquid state, for example, water or refrigerant.

The vapor/gas pressurizer 12 is connected to the pipe unit 11. The vapor/gas pressurizer 12 is used to compress the heat-transfer medium in the pipe unit 11 to the gas state with a high temperature and high pressure. The vapor/gas pressurizer 12 can be a compressor.

The heat dissipation device 13 is connected to the pipe unit 11, and disposed behind the vapor/gas pressurizer 12, and that is, the vapor/gas pressurizer 12 is connected to the heat dissipation device 13 via the pipe unit 11. The heat dissipation device 13 comprises a heat dissipation fin bank 131 and a fan 132, and after the heat-transfer medium flows to the heat dissipation fin bank 131, the cooling process begins via the fan 132, such that the heat-transfer medium in the pipe unit 11 can be converted into the liquid state with the low temperature and the high pressure. For example, the heat dissipation device 13 comprises one of the heat dissipation fin bank 131, the fan 132 and a water cooling heat dissipation device. The water cooling heat dissipation device is a tank being full of water, and the heat dissipation fin bank 131 or the pipe unit 11 is soaked in the tank being full of water to form the water cooling heat dissipation device, so as to achieve the heat dissipation effect.

The throttling device 14 is connected to the pipe unit 11, and disposed behind the heat dissipation device 13, and that is, the heat dissipation device 13 is connected to the throttling device 14 via the pipe unit 11. The throttling device 14 is a capillary, a temperature-sensitive expansion valve, an electronic expansion valve or an oriface, and the throttling device 14 is used to convert the heat-transfer medium in the pipe unit 11 into the gas state with the low temperature and the low pressure.

The heat sink 15 is connected to pipe unit 11, and the heat sink 15 is disposed between the throttling device 14 and the vapor/gas pressurizer 12, and that is, the throttling device 14 is connected to the heat sink 15 via the pipe unit 11, and the heat sink 15 is connected to the vapor/gas pressurizer 12 via the pipe unit 11. The heat sink 15 has a heat sinking surface 151 thereon, and the heat sinking surface 151 can contact a heat source H and perform cold and heat exchange for the heat source H. Generally, the heat source H transfer the heat to the heat sinking surface 151 to decrease the temperature of the heat source H, or to keep the temperature of the heat source H at a specific temperature. The heat-transfer medium in the gas state with the low temperature and the low pressure, which flows to the heat sink 15, passes the heat sinking surface 151, and takes out the heat transferred from the heat source H, thus converting the heat-transfer medium into the gas state with the high temperature and the low pressure. Next, the heat-transfer medium flows to the vapor/gas pressurizer 12 via the pipe unit 11 again, so as to complete a cycle loop.

The control unit 16 is electrically connected and signaling to the vapor/gas pressurizer 12, the heat dissipation device 13, the throttling device 14 and the heat sink 15, thus controlling and providing electricity to the vapor/gas pressurizer 12, the heat dissipation device 13, the throttling device 14 and the heat sink 15.

The vapor/gas pressurizer 12, the heat dissipation device 13, the throttling device 14 and the control unit 16 are disposed inside the case 20, and the heat sink 15 is disposed outside the case 20.

To further facilitate the person with the ordinary skill in the art to understand the structure, means and results of the heat exchange device 10 provided by the present disclosure, details and usage of the heat exchange device 10 are illustrated as follows.

Referring to FIG. 3, the case 20 can make the heat exchange device 10 integrated into one product, such that it is convenient for the user to bring and install it. When activating the heat exchange, the user merely needs to make the heat sinking surface 151 of the heat sink 15 contact the heat source H. In the embodiment, the heat source H can be a chip, such as a central processing unit, and the heat sinking surface 151 can exchange the heat via the heat-transfer medium in the pipe unit 11, which has the gas stage with the low temperature and the low pressure. Therefore, the heat generated by the heat source H can be absorbed, and the heat-transfer medium is converted into the gas state with the high temperature and the low pressure. Next, the heat-transfer medium is output to the vapor/gas pressurizer 12 via the pipe unit 11, and the vapor/gas pressurizer 12 compresses the heat-transfer medium, therefore converting the heat-transfer medium into the gas state with the high temperature and the high pressure. Next, the heat-transfer medium is input to the heat dissipation fin bank 131 of the heat dissipation device 13 via the pipe unit 11, and the fan 132 is used to exhaust the heat of the heat-transfer medium to decrease the temperature of the heat-transfer medium. Then, the heat-transfer medium in the pipe unit 11 is converted into the liquid state with the low temperature and the higher pressure. Next, the throttling device 14, such as the capillary, converts the heat-transfer medium into the gas state with the low temperature and the low pressure. Thus, the heat-transfer medium flowing into the heat sink 15 has the gas state with the low temperature and the low pressure, and the cycle loop is completed. The cycle loop can make sure that the temperature of the heat-transfer medium flowing to the heat sinking surface 151 is sufficiently low to efficiently dissipate the heat of the heat source H. Accordingly, after the long-term usage, the temperature of the central processing unit being running can be kept in a proper operation temperature range.

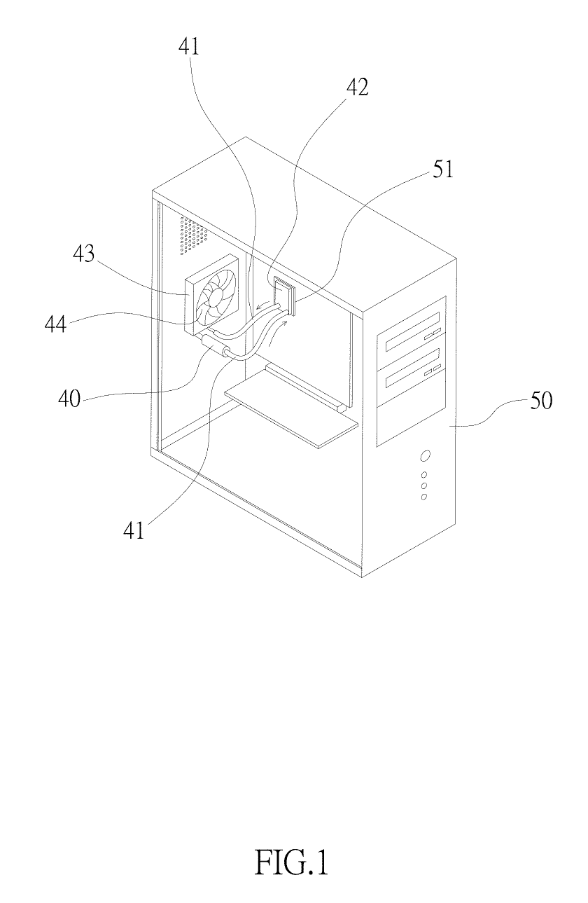

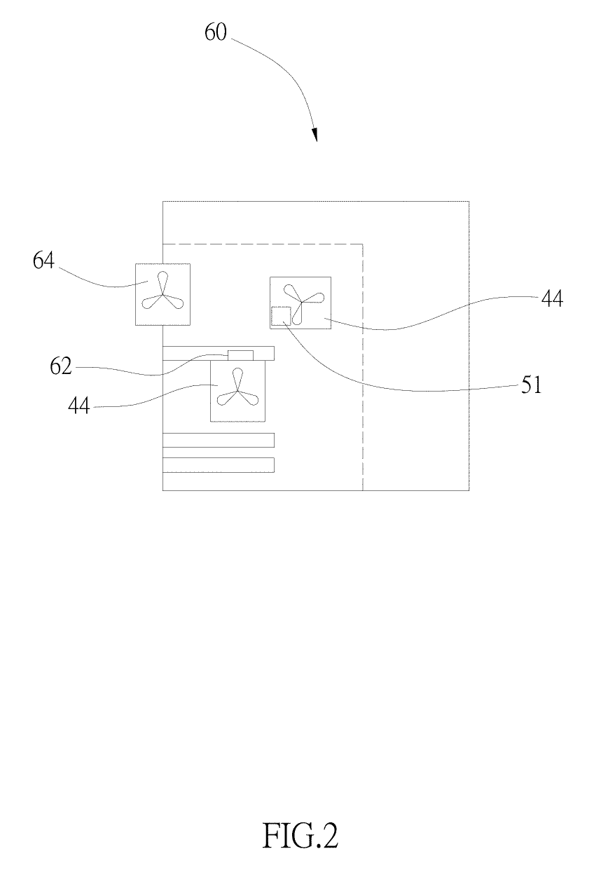

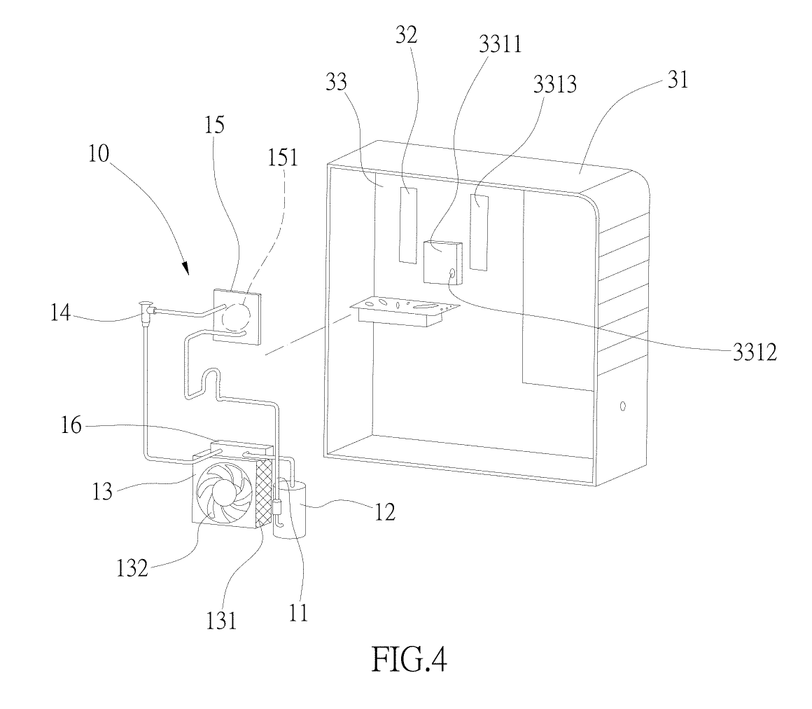

Referring to FIG. 1 through FIG. 4 simultaneously, FIG. 4 is a three-dimensional explosive diagram of an equipment system which has the heat exchange device of the first embodiment, and the heat exchange device illustrated herein is same as that in the previous embodiment, therefore omitting the redundant descriptions. The heat exchange device 10 can be directly installed in an equipment 30 to form the equipment system, the equipment 30 can be a host computer, a container or a building, and the equipment 30 in the embodiment is the host computer, for example. The equipment 30 has a housing 31, and the housing 31 in the embodiment is the computer case, for example. The housing 31 or the equipment 30 further has a power supply 32 and a working unit 33, wherein the power supply 32 and the working unit 33 are disposed inside the housing 31 and the equipment 30. The working unit 33 is a motherboard 331, and the motherboard 331 has a central processing unit 3311 thereon (the central processing unit 3311 in the embodiment is the heat source). The heat exchange device 10 has the heat sink 15 corresponding to the working unit 33, wherein the heat sinking surface 151 contacts the central processing unit 3311. Meanwhile, the power supply 32 can directly provide electricity to the heat exchange device 10, and thus heat exchange device 10 does not need the external power source. Generally, the contacting area of the heat sink 15 is small, and the power consumption of the vapor/gas pressurizer 12 is not large, such that the heat exchange device 10 directly uses the electricity provided by the power supply 32 without affecting the performance and stability of the working unit 33. Meanwhile, the motherboard 331 of the working unit 33 further has temperature sensor 3312 disposed between the heat sink 15 and the central processing unit 3311, and the temperature sensor 3312 is clamped between the heat sink 15 and the central processing unit 3311, and contacts the heat sinking surface 151 of the heat sink 15. The motherboard 331 further has a pulse width modulation (PWM) gearing device 3313 thereon, the control unit 16 is electrically connected and signaling to the pulse width modulation gearing device 3313 to control the heat exchange device 10. When the working unit 33 is booted up, and the temperature of the central processing unit 3311 is low than a threshold, the control unit 16 does not boot up the vapor/gas pressurizer 12 and the fan 132. After the working unit 33 runs for a period, the temperature of the central processing unit 3311 on working unit 33 increases, the temperature sensor 3312 can sense that the temperature of the central processing unit 3311 has increased. When the temperature sensor 3312 senses that the temperature of the central processing unit 3311 equals to or exceeds the threshold, the pulse width modulation gearing device 3313 indicates the control unit 16 via a signal, and the control unit 16 instantly drives the vapor/gas pressurizer 12 and the fan 132 to run, so as to decrease the temperature of the central processing unit 3311 via the cycle loop of the heat-transfer medium. When the temperature of the central processing unit 3311 has decreased with a certain degree, for example, the temperature sensor 3312 senses that the temperature of the central processing unit 3311 is less than the threshold, the pulse width modulation gearing device 3313 indicates the control unit 16 via another signal, and the control unit 16 stops or slows the operation of the heat exchange device 10. Thus, the heat exchange device 10 runs on demands, the energy consumption can be decreased, and the over heat dissipation of the heat sink 15 can be avoided, wherein the over heat dissipation may cause frost to be formed on the central processing unit 3311 and the working unit 33, or the too low temperatures of the central processing unit 3311 and the working unit 33.

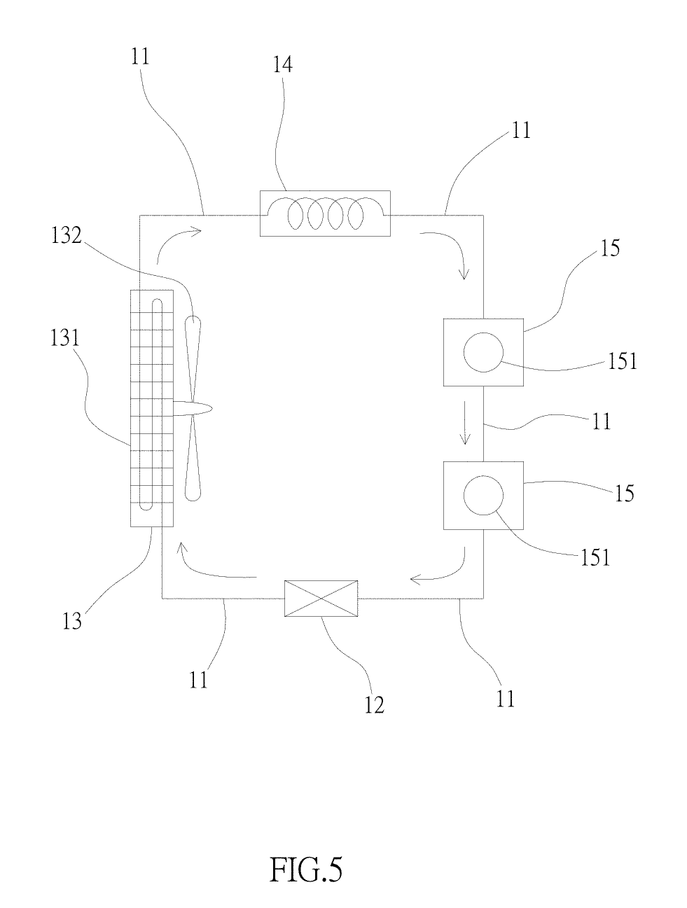

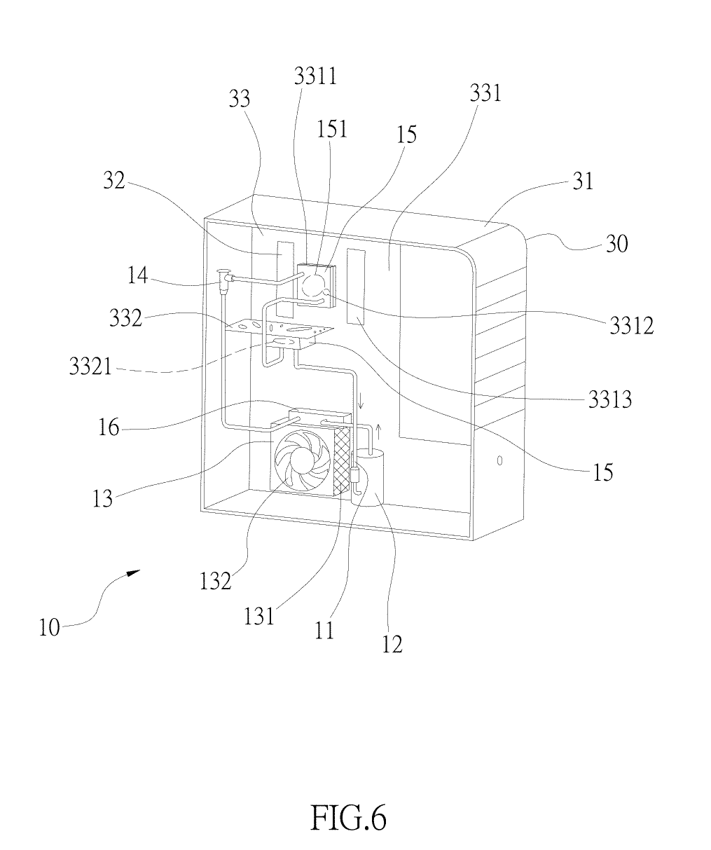

Referring to FIG. 5 and FIG. 6, which show another equipment system having the heat exchange device of the first embodiment, the heat exchange device 10 herein is the same as that in the previous embodiment, thus omitting the redundant descriptions. The equipment 30 has the working units 33 therein, and the heat exchange device 10 in the embodiment has the heat sinks 15, the heat sinks 15 are connected via the pipe unit 11 to carry out the cycle loop. Preferably, the heat sinks 15 are connected via the pipe unit 11 in a serial connection manner; and most preferably, the heat sinks 15 are sequentially connected via the pipe unit 11 to form the cycle loop. The heat sinking surface 151 of the heat sink 15 contacts the central processing unit 3311 (the central processing unit 3311 in the embodiment is the heat source); preferably, the heat sinking surface 151 contacts the corresponding central processing unit 3311 (the central processing unit 3311 in the embodiment is the heat source); and most preferably, each of the heat sinking surfaces 151 contact the corresponding one of the central processing units 3311 (the central processing unit 3311 in the embodiment is the heat source).

In the embodiment of FIG. 5 and FIG. 6, interior of the equipment 30 has the working units 33, the two working units 33 are respectively the motherboard 331 and a graphics display card 332, the motherboard 331 has the central processing unit 3311 thereon, and the graphics display card 332 has a graphics processing unit 3321 thereon. The heat exchange device 10 has the two heat sinks 15 corresponding to the two working units 33, wherein the two heat sinks 15 are sequentially connected via the pipe unit 11. The two heat sinks 15 respectively contact the central processing unit 3311 and the graphics processing unit 3321 via their heat sinking surfaces 151. Certainly, the equipment 30 further has the power supplies 32, which are switched to provide electricity to the working units 33 or the heat exchange device 10 in response to the demand of the electricity allocation.

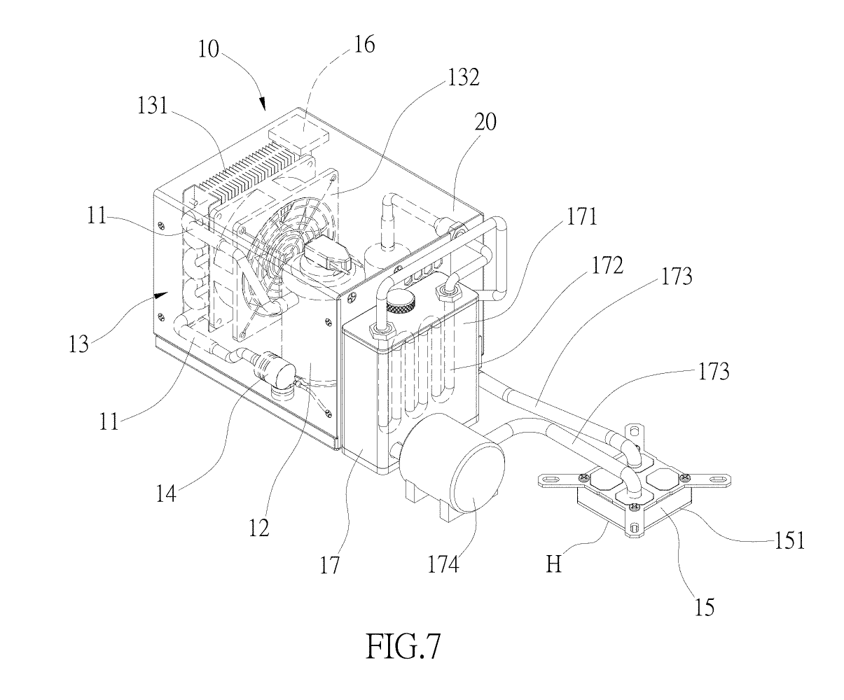

Referring to FIG. 7, which is a schematic diagram showing a whole structure configuration of a heat exchange device according to a second embodiment of the present disclosure, the heat exchange device exchanges heat via the water cooling manner. The heat exchange device 10 comprises pipe units 11, a vapor/gas pressurizer 12, a heat dissipation device 13, a throttling device 14, a heat sink 15, a control unit 16, a heat conduction cycling box 17 and a case 20.

The pipe units 11 are filled with the heat-transfer medium (not shown in the drawings), and the heat-transfer medium is material which is able to be changed between a gas state and liquid state, for example, water or refrigerant, but the heat-transfer medium is not limited to be water or refrigerant.

The vapor/gas pressurizer 12 are corresponding connected to the pipe units 11. In one preferred embodiment, the vapor/gas pressurizer 12 can compress the heat-transfer medium in the pipe units 11 to the gas state with a high temperature and high pressure. The vapor/gas pressurizer 12 can be a compressor, for example, but the vapor/gas pressurizer 12 is not limited to be the compressor.

The heat dissipation device 13 is correspondingly connected to the vapor/gas pressurizer via the pipe unit 11. The heat dissipation device 13 comprises a heat dissipation fin bank 131 and a fan 132. Further, the heat dissipation device 13 can be a water cooling heat dissipation device. In a preferred embodiment of the present disclosure, the heat dissipation device 13 is connected to the vapor/gas pressurizer 12 via the pipe unit 11, and the heat dissipation device 13 is formed by the heat dissipation fin bank 131 and the fan 132. After the heat-transfer medium in the pipe unit 11 flows to the heat dissipation fin bank 131, the cooling process begins via the fan 132, such that the heat-transfer medium in the pipe unit 11 can be converted into the liquid state with the low temperature and the high pressure.

The throttling device 14 is correspondingly connected to the heat dissipation device 13 via the pipe unit 11. Further, the throttling device 14 is a capillary, a temperature-sensitive expansion valve, an electronic expansion valve or an oriface. In a preferred embodiment of the present disclosure, the throttling device 14 is correspondingly connected to the heat dissipation device 13 via the pipe unit 11, and the throttling device 14 is used to convert the heat-transfer medium in the pipe unit 11 into the gas state with the low temperature and the low pressure, thus achieving the evaporative freezing objective.

The heat sink 15 is correspondingly connected to the throttling device 14 and the vapor/gas pressurizer 12 via the pipe units 11, wherein the heat sink 15 has a heat sinking surface 151. In a preferred embodiment of the present disclosure, the heat sink 15 is correspondingly connected to the throttling device 14 and the vapor/gas pressurizer 12 via the pipe units 11, wherein the heat sink 15 has the heat sinking surface 151, the heat sinking surface 151 contacts a heat source H for exchanging the heat of the heat source H, and the heat of the heat source H is generated from the operation of a chip (for example, the central processing unit). Generally, the heat source H transfer the heat to the heat sinking surface 151 to decrease the temperature of the heat source H, or to keep the temperature of the heat source H at a specific temperature. The heat-transfer medium in the liquid state with the low temperature and the low pressure, which flows to the heat sink 15, passes the heat sinking surface 151, and takes out the heat transferred from the heat source H, thus converting the heat-transfer medium into the gas state with the high temperature and the low pressure. Next, the heat-transfer medium flows to the vapor/gas pressurizer 12 via the pipe unit 11 again, so as to complete a cycle loop.

The control unit 16 is electrically connected and signaling to the vapor/gas pressurizer 12, the heat dissipation device 13, the throttling device 14 and the heat sink 15. In a preferred embodiment of the present disclosure, the control unit 16 is electrically connected and signaling to the vapor/gas pressurizer 12, the heat dissipation device 13, the throttling device 14 and the heat sink 15, thus controlling and providing electricity to the vapor/gas pressurizer 12, the heat dissipation device 13, the throttling device 14 and the heat sink 15.

The heat conduction cycling box 17 comprises a box body 171, cooling liquid and an inner pipe 172 disposed in the box body 171, and a cooling pipe 173, wherein two ends of the inner pipe 172 are correspondingly connected to the pipe unit 11. Further, the inner pipe 172 is configured to have continuous U shape tubes, but the present disclosure is not limited thereto, and the inner pipe can be configured in other heat exchange type. Moreover, the heat conduction cycling box 17 further has a drive part 174 for driving operation of the cooling liquid in the heat conduction cycling box 17. In a preferred embodiment of the present disclosure, the heat conduction cycling box 17 is formed by the combination of the box body 171, the inner pipe 172 having the continuous U shape tubes, and the cooling pipe 173, wherein the cooling pipe 173 is filled with the cooling liquid, the inner pipe 172 having the continuous U shape tubes can efficiently enhance the heat exchange efficiency of the cooling liquid in the heat conduction cycling box 17, the two ends of the cooling pipe 173 are correspondingly connected to the heat sink 15 to transfer the heat by a cycle manner, and the drive part 174 drives the cooling liquid to flow in the cooling pipe 173 and the heat conduction cycling box 17 by the cycle manner.

The vapor/gas pressurizer 12, the heat dissipation device 13, the throttling device 14 and the control unit 16 are disposed inside the case 20, and the heat sink 15 and the heat conduction cycling box 17 are disposed outside the case 20. In a preferred embodiment of the present disclosure, the heat exchange device 10 can be received in the case, such that it is easy to bring and install the heat exchange device 10. When activating the heat exchange, the user merely needs to make the heat sinking surface 151 of the heat sink 15 contact the heat source H. The heat sinking surface 151 can uses the heat-transfer medium filled in the inner pipe 172, having the liquid state with the low temperature and the low pressure, to achieve the heat exchange. Thus, the heat generated from the heat source H is absorbed by the heat-transfer medium, and the heat-transfer medium is converted to the gas state with the high temperature and the low pressure. Next, the heat-transfer medium flows to vapor/gas pressurizer 12 from the inner pipe 172 via the pipe unit 11, and after the heat-transfer medium is compressed to convert into the gas state with the high temperature and high pressure, the heat-transfer medium is input to the heat dissipation fin bank 131 of the heat dissipation device 13 via the pipe unit 11, and the fan 132 is used to exhaust the heat of the heat-transfer medium to decrease the temperature of the heat-transfer medium. Then, the heat-transfer medium in the pipe unit 11 is converted into the liquid state with the low temperature and the higher pressure. Next, the throttling device 14, such as the capillary, converts the heat-transfer medium into the liquid state with the low temperature and the low pressure. Thus, the heat-transfer medium flowing into the heat sink 15 has the gas state with the low temperature and the low pressure, and the cycle loop is completed. The cycle loop can make sure that the temperature of the heat-transfer medium flowing to the heat sinking surface 151 which contacts the cooling pipe 173 is sufficiently low to efficiently dissipate the heat of the heat source H, such that the heat sinking surface 151 can carry out the heat exchange. Accordingly, after the long-term usage, the temperature of the central processing unit being running can be kept in a proper operation temperature range.

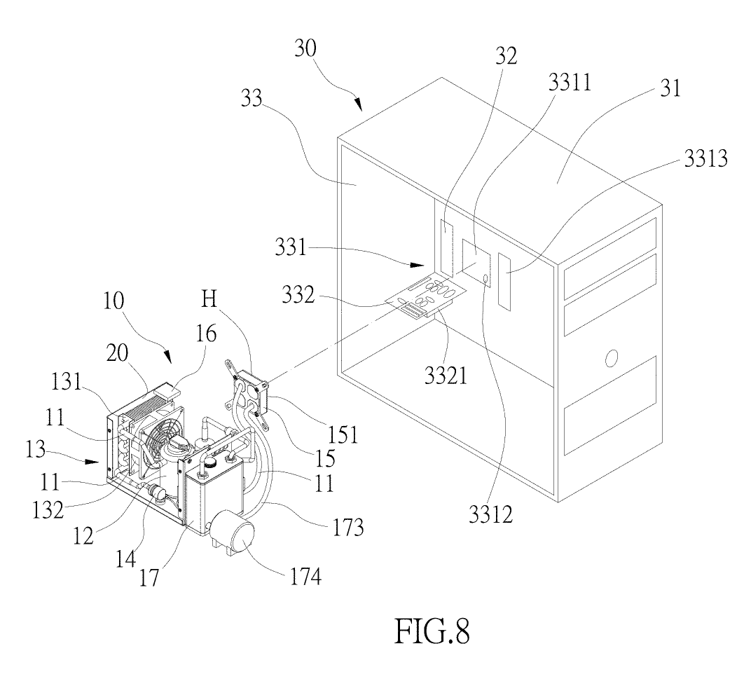

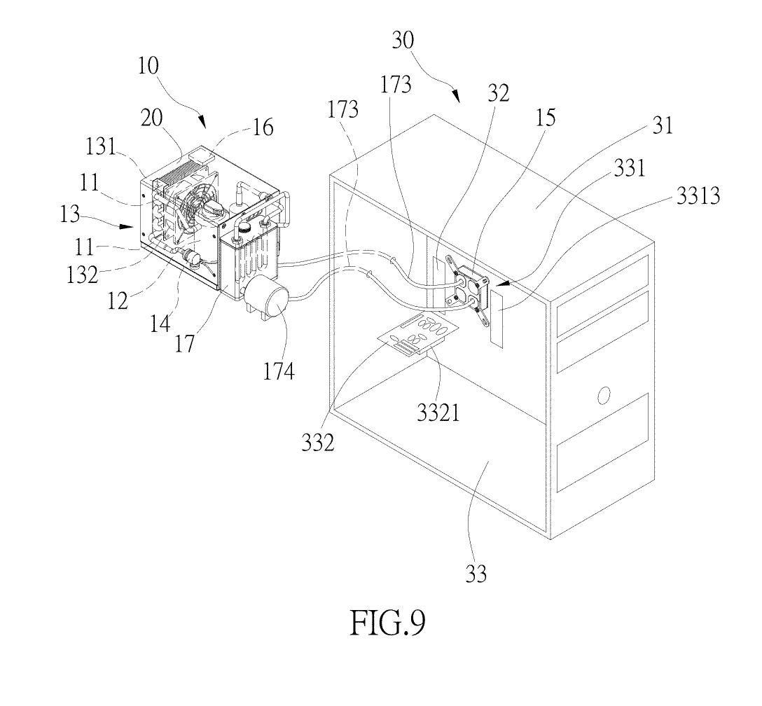

Further, referring to FIG. 8 and FIG. 9, which are respectively a three-dimensional explosive diagram of an equipment system which has the heat exchange device of the second embodiment and a schematic diagram showing a whole structure configuration of the equipment system of FIG. 8, the heat exchange device 10 herein is the same as that of the second embodiment, and thus the redundant descriptions are omitted. The heat exchange device 10 is directly installed in an equipment 30 to form the equipment system, the equipment 30 can be a host computer, a container or a building, and the equipment 30 in a preferred embodiment of the present disclosure is the host computer. The equipment 30 has a housing 31, and the housing 31 in a preferred embodiment of the present disclosure is the computer case. The housing 31 or the equipment 30 further has a power supply 32 and a working unit 33 therein, the working unit 33 is a motherboard 331, and the motherboard 331 has a central processing unit 3311 thereon (the central processing unit 3311 in the embodiment is the heat source). The heat exchange device 10 has the heat sink 15 corresponding to the working unit 33, wherein the heat sinking surface 151 contacts the central processing unit 3311. Meanwhile, the power supply 32 can directly provide electricity to the heat exchange device 10, and thus heat exchange device 10 does not need the external power source. Generally, the contacting area of the heat sink 15 is small, and the power consumption of the vapor/gas pressurizer 12 is not large, such that the heat exchange device 10 directly uses the electricity provided by the power supply 32 without affecting the performance and stability of the working unit 33. Meanwhile, the motherboard 331 of the working unit 33 further has temperature sensor 3312 thereon, and the temperature sensor 3312 is clamped between the heat sink 15 and the central processing unit 3311, and contacts the heat sinking surface 151 of the heat sink 15. The motherboard 331 further has a pulse width modulation (PWM) gearing device 3313 thereon, the control unit 16 is electrically connected and signaling to the pulse width modulation gearing device 3313 to control the heat exchange device 10. When the working unit 33 is booted up, and the temperature of the central processing unit 3311 is low than a threshold, the control unit 16 does not boot up the vapor/gas pressurizer 12 and the fan 132. After the working unit 33 runs for a period, the temperature of the central processing unit 3311 on working unit 33 increases, the temperature sensor 3312 can sense that the temperature of the central processing unit 3311 has increased. When the temperature sensor 3312 senses that the temperature of the central processing unit 3311 equals to or exceeds the threshold, the pulse width modulation gearing device 3313 indicates the control unit 16 via a signal, and the control unit 16 instantly drives the vapor/gas pressurizer 12 and the fan 132 to run, so as to decrease the temperature of the central processing unit 3311 via the cycle loop of the heat-transfer medium. When the temperature of the central processing unit 3311 has decreased with a certain degree, for example, the temperature sensor 3312 senses that the temperature of the central processing unit 3311 is less than the threshold, the pulse width modulation gearing device 3313 indicates the control unit 16 via another signal, and the control unit 16 stops or slows the operation of the heat exchange device 10. Thus, the heat exchange device 10 runs on demands, the energy consumption can be decreased, and the over heat dissipation of the heat sink 15 can be avoided, wherein the over heat dissipation may cause frost to be formed on the central processing unit 3311 and the working unit 33, or the too low temperatures of the central processing unit 3311 and the working unit 33.

Additionally, interior of the equipment 30 has the working units 33, the two working units 33 are respectively the motherboard 331 and a graphics display card 332, the motherboard 331 has the central processing unit 3311 thereon, and the graphics display card 332 has a graphics processing unit 3321 thereon. The heat exchange device 10 has the two heat sinks 15 corresponding to the two working units 33, wherein the two heat sinks 15 are sequentially connected via the cooling pipe 173. The two heat sinks 15 respectively contact the central processing unit 3311 and the graphics processing unit 3321 via their heat sinking surfaces 151.

Further, a rated power of the central processing unit 3311 is more than or equal to 95 W, a rated power of the graphics processing unit 3321 is more than or equal to 150 W, and the heat exchange device 10 is dedicated to dissipate heat of 250 W through 600 W.

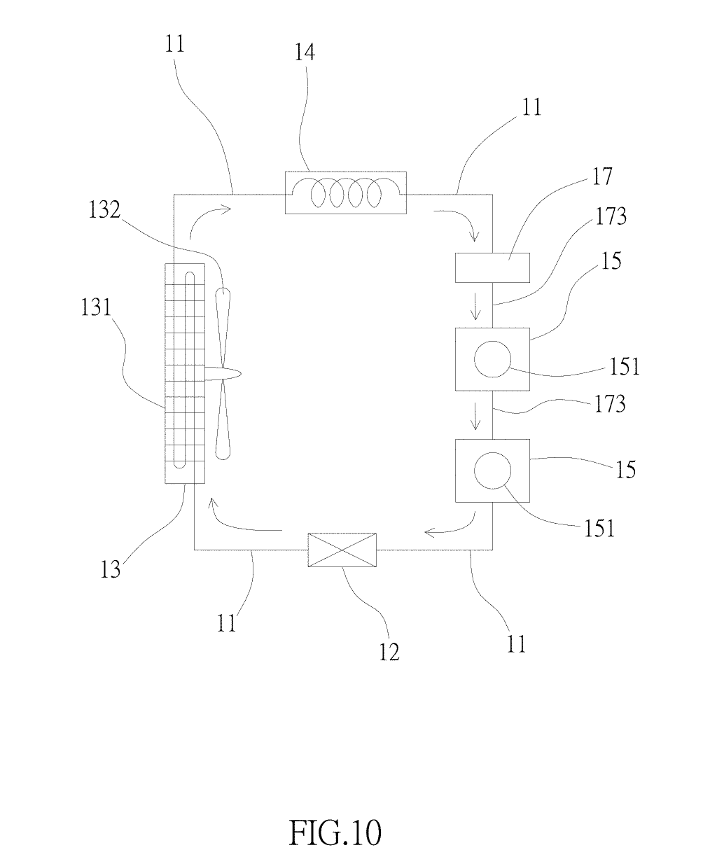

Moreover, referring to FIG. 10, which is a block diagram of another equipment system which has the heat exchange device of the second embodiment, the heat exchange device 10 herein is the same as that of the second embodiment, and thus the redundant descriptions are omitted. Interior of the equipment 30 has the working units 33, the heat exchange device 10 in the embodiment has the heat sinks 15, and the heat sinks 15 are connected via the pipe unit 11 to form the cycle loop. Preferably, the heat sinks 15 are serially connected via the cooling pipe 173 to form the cycle loop; and most preferably, the heat sinks 15 are sequentially connected via the cooling pipe 173 to form the cycle loop. The heat sinking surface 151 of the heat sink 15 contacts the central processing unit 3311; preferably, the heat sinking surface 151 of the heat sink 15 correspondingly contacts the central processing unit 3311; and preferably, each of the heat sinking surfaces 151 contacts the corresponding one of the central processing units 3311.

The heat exchange device and the equipment system using the heat exchange device in the embodiment utilize the hardware design of filling the heat-transfer medium in the pipe unit, and via the cycle of the vapor/gas pressurizer, the heat dissipation device and the throttling device, the heat-transfer medium flowing to the heat sink efficiently takes out the heat by using the heat sinking surface. Further, the heat conduction cycling box can stably and quickly exchange the heat of the heat source, thus achieving the efficient heat exchange cycle and quick heat dissipation.

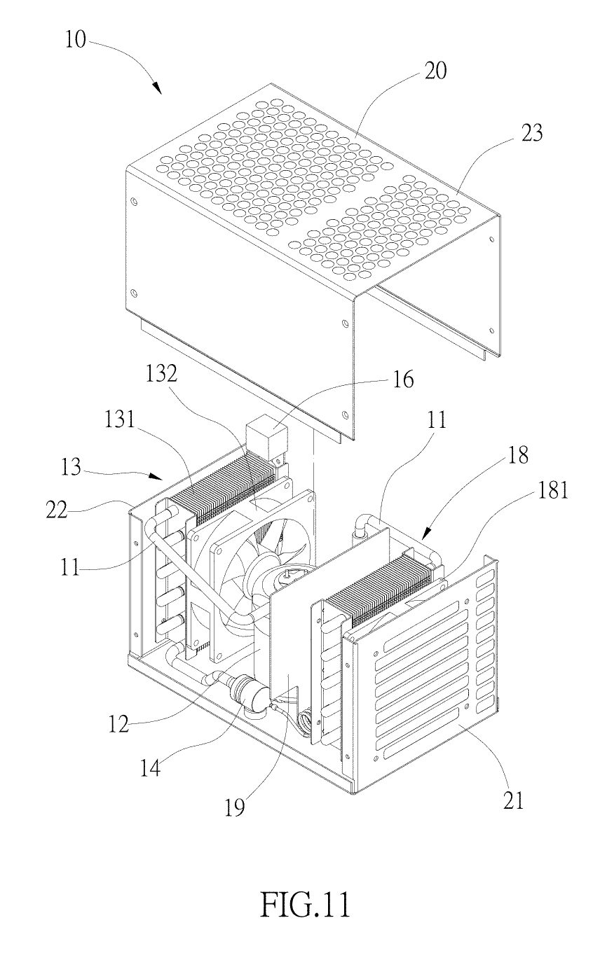

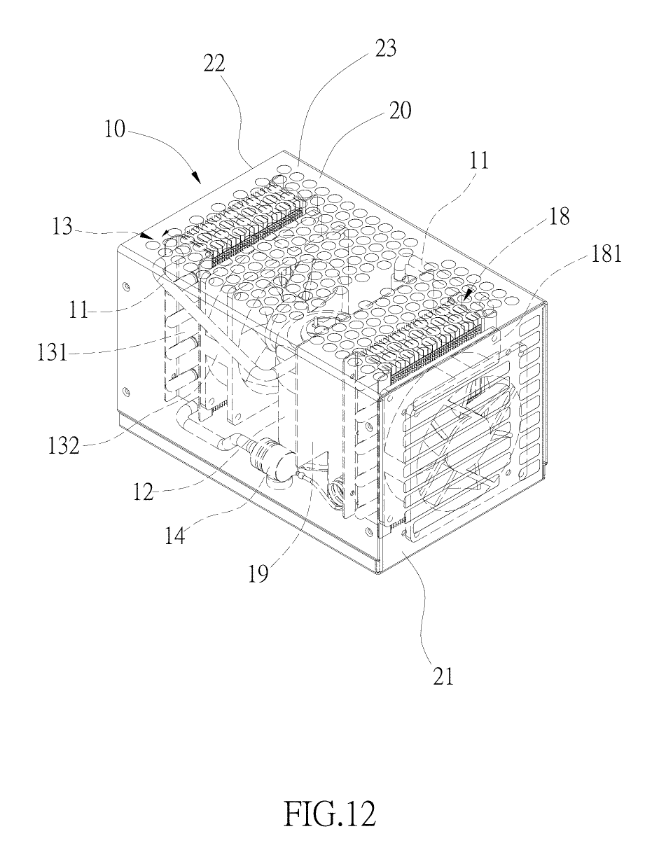

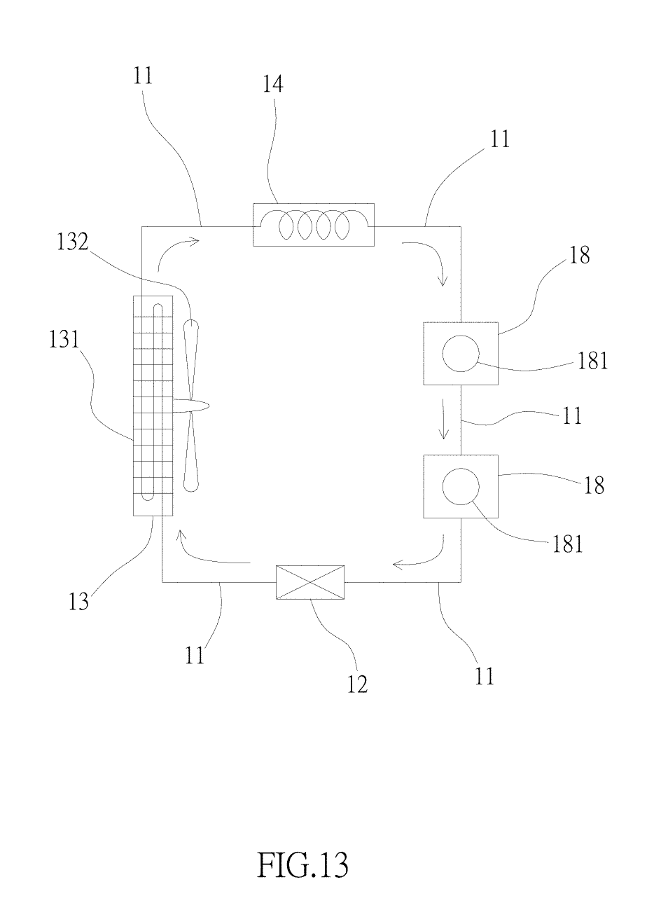

Refer to FIG. 11 through FIG. 13, which are respectively a three-dimensional view of a heat exchange device according to a third embodiment of the present disclosure, a schematic diagram showing a whole structure configuration of the heat exchange device of FIG. 11, and a block diagram of the heat exchange device of FIG. 11. The heat exchange device 10 can perform the cold air cycle and the exchange of the cool and hot air. In the third embodiment of the present disclosure, the heat exchange device 10 is used to dissipate the heat of the host computer, and comprises pipe units 11, a vapor/gas pressurizer 12, a heat dissipation device 13, a throttling device 14, a cooler 18, a control unit 16 and a case 20.

The pipe units 11 are filled with heat-transfer medium (not shown in the drawings), and the heat-transfer medium is material which is able to be changed between a gas state and liquid state, for example, refrigerant.

The vapor/gas pressurizer 12 is correspondingly connected to the pipe units 11. In a preferred embodiment of the present disclosure, the vapor/gas pressurizer 12 is used to compress the refrigerant in the pipe units 11 to the gas state with a high temperature and high pressure. The vapor/gas pressurizer 12 can be a compressor, and the present disclosure is not limited thereto.

The heat dissipation device 13 is connected to the vapor/gas pressurizer 12 via the pipe units 11. Additionally, the heat dissipation device 13 comprises a heat dissipation fin bank 131 and a fan 132. Further, the heat dissipation device 13 is a water cooling heat dissipation device. In a preferred embodiment of the present disclosure, the heat dissipation device 13 is connected to the vapor/gas pressurizer 12 via the pipe unit 11, the heat dissipation device 13 is formed by the heat dissipation fin bank 131 and the fan 132, and one side of the heat dissipation fin bank 131 has the fan 132, and after the refrigerant in the pipe unit 11 flows to the heat dissipation fin bank 131, the cooling process begins via the fan 132, such that the refrigerant in the pipe unit 11 can be converted into the liquid state with the low temperature and the high pressure.

The throttling device 14 is correspondingly connected to the heat dissipation device 13 via the pipe unit 11. The throttling device 14 is a capillary, a temperature-sensitive expansion valve, an electronic expansion valve or an oriface. In a preferred embodiment of the present disclosure, the throttling device 14 is correspondingly connected to the heat dissipation device 13 via the pipe unit 11, and the throttling device 14 is used to convert the refrigerant in the pipe unit 11 into the gas state with the low temperature and the low pressure, thus achieving the evaporative freezing objective.

The cooler 18 is correspondingly connected to the throttling device 14 and the vapor/gas pressurizer 12 via the pipe units 11, wherein the cooler 18 has an air blower 181. Further, the air blower 181 is a fan. In a preferred embodiment of the present disclosure, the cooler 18 is correspondingly connected to the throttling device 14 and the vapor/gas pressurizer 12 via the pipe units 11, wherein the cooler 18 has the air blower 181 thereon, by using the refrigerant transmitted by the throttling device 14, an freezing objective for the air can be achieved, the air blower 181 is used send the cold air to the middle of the host computer for cycling, and the heat source H inside the host computer is the central processing unit (not shown in the drawings), which generates the hot air when operating, wherein the cold air and the hot form the nature convection due to the temperature difference, and the cold air flows downward and the hot air flows upward, to form a cycle loop, therefore helping to decrease the usage environment temperature of the electronic component of the equipment 30 and improving the lifetime and heat dissipation ability of the product.

The control unit 16 is electrically connected and signaling to the vapor/gas pressurizer 12, the heat dissipation device 13, the throttling device 14 and the cooler 18. In a preferred embodiment of the present disclosure, the control unit 16 is electrically connected and signaling to the vapor/gas pressurizer 12, the heat dissipation device 13, the throttling device 14 and the cooler 18, thus controlling and providing electricity to the vapor/gas pressurizer 12, the heat dissipation device 13, the throttling device 14 and the cooler 18.

The vapor/gas pressurizer 12, the heat dissipation device 13, the throttling device 14, the cooler 18 and the control unit 16 are disposed inside the case 20. Further, the case 20 further has a first side plate 21, a second side plate 22 being opposite to the first side plate 21, and a third side plate 23 covering and disposed on top portions of the first side plate 21 and the second side plate 22. The first side plate 21, the second side plate 22 and the third side plate 23 forms an reception space, and the vapor/gas pressurizer 12, the heat dissipation device 13, the throttling device 14, the cooler 18 and the control unit 16 are disposed in the reception space.

Further, a clapboard 19 is disposed between the vapor/gas pressurizer 12 and the cooler 18. In a preferred embodiment of the present disclosure, the clapboard 19 is disposed between the vapor/gas pressurizer 12 and the cooler 18, so as to isolate the cold air and the hot air.

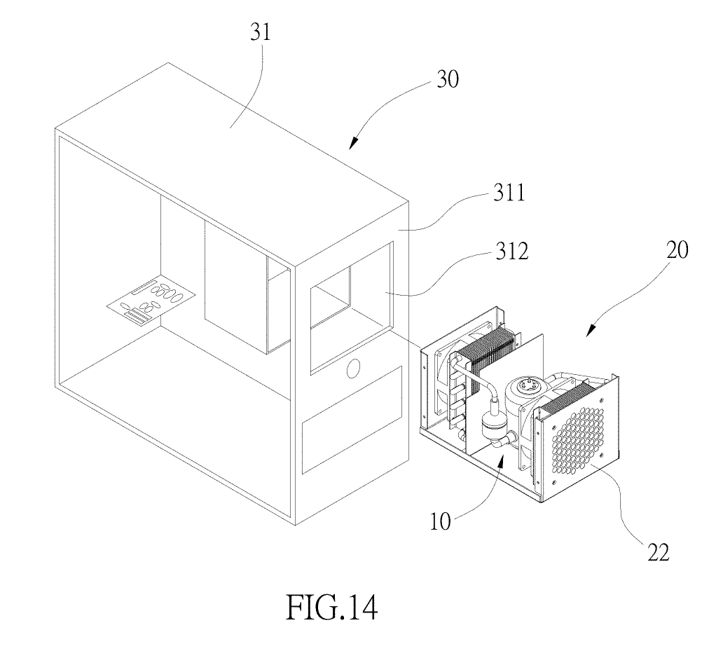

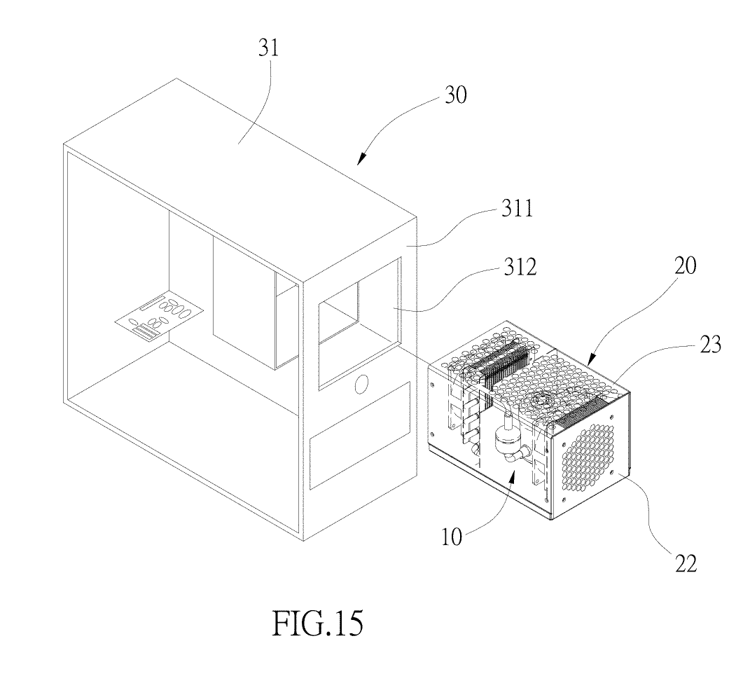

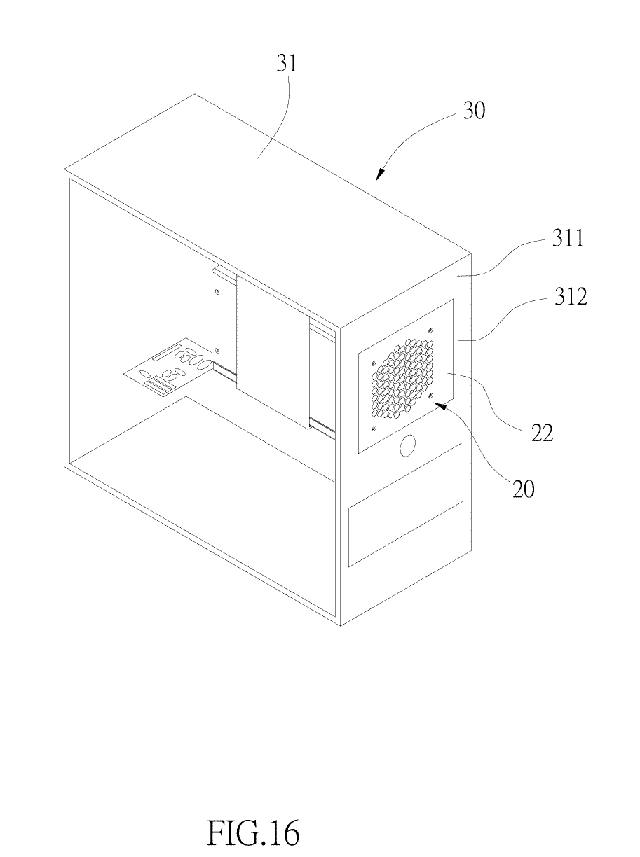

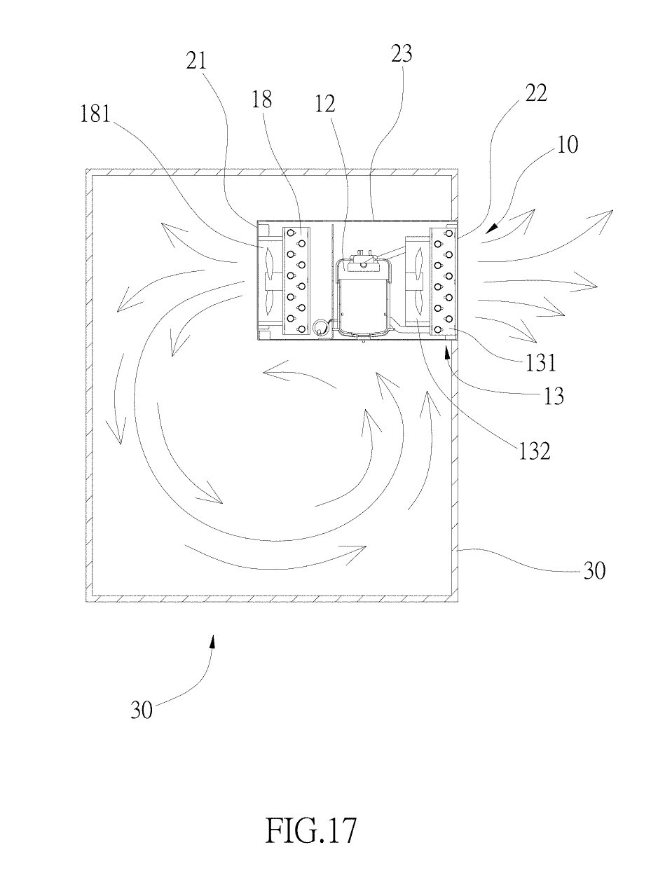

Further, refer to FIG. 14 through FIG. 17, wherein FIG. 14 is a three-dimensional explosive diagram of an equipment system which has the heat exchange device of the third embodiment, FIG. 15 is another three-dimensional explosive diagram of the equipment system which has the heat exchange device of the third embodiment, FIG. 16 is a three-dimensional diagram of the equipment system which has the heat exchange device of the third embodiment, and FIG. 17 is a schematic diagram showing operation of the equipment system which has the heat exchange device of the third embodiment. The heat exchange device 10 herein is the same as that mentioned in the above descriptions, and the redundant descriptions are omitted. The heat exchange device 10 is installed in an equipment 30 to form the equipment system, the equipment 30 can be a host computer, a container or a building, and the equipment 30 in the preferred embodiment is the host computer, for example. The equipment 30 has a housing 31, a terminal portion of the housing 31 has a side plate 311, and the side plate 311 has through hole 312 thereon, wherein the case 20 is disposed on an inner top portion of the housing 31, such that the heat exchange device 10 is disposed at the through hole 312. In a preferred embodiment of the present disclosure, the housing is the computer case, a terminal portion of the housing 31 has the side plate 311, and the through hole 312 is disposed on the side plate 311. After the refrigerant in the pipe units 11 is compressed to the gas state with the high temperature and the high pressure by the vapor/gas pressurizer 12, the cooling process begins via the heat dissipation device 13, such that the refrigerant can be converted into the liquid state with the low temperature and the high pressure. Next, the throttling device 14 converts the refrigerant into the liquid state with the low temperature and the low pressure, the cooler 18 freezes the refrigerant, and the air blower 181 next sends the cold air to the middle of the host computer for cycling. The hot air generated by the host computer or the hot air generated by the operation of the vapor/gas pressurizer 12 flow into the case via the third side plate 23, and the fan exhaust the hot air to the outside the case 20 and the outside of the housing 31, so as to exchange the hot air and the cold air, such that the system temperature inside the equipment 30 is usually about 35° C. through 45° C., and by using the heat exchange device 10, the system temperature inside the equipment 30 can be decreased to 10° C. through 15° C.

Further, equipment 30 further has a power supply (not shown in the drawings), wherein the power supply is electrically connected to the heat exchange device 10 for providing the required electricity to the operation of the exchange device 10. The equipment 30 can further have temperature sensor (not shown in the drawings), wherein the temperature sensor contacts the cooler 18 to senses the contacting temperature of the cooler 18. Further, the equipment 30 further has a pulse width modulation gearing device (not shown in the drawings), wherein the control unit 16 is electrically connected and signaling to the pulse width modulation gearing device. When the temperature sensor senses that the temperature of the central processing unit equals to or exceeds the threshold, the pulse width modulation gearing device indicates the control unit via a signal, and the control unit 16 instantly drives the vapor/gas pressurizer 12 and the fan 132 to run, so as to decrease the temperature of the central processing unit via the cycle loop of the heat-transfer medium. When the temperature of the central processing unit has decreased with a certain degree, for example, the temperature sensor senses that the temperature of the central processing unit is less than the threshold, the pulse width modulation gearing device indicates the control unit 16 via another signal, and the control unit 16 stops or slows the operation of the heat exchange device 10.

The heat exchange device and the equipment system using the heat exchange device in the embodiment utilize the hardware design of filling the heat-transfer medium in the pipe unit, and via the cycle of the vapor/gas pressurizer, the heat dissipation device and the throttling device, the refrigerant efficiently flows to the cooler to form the cold air, and the cold air is transmitted to the interior of the equipment, such that the hot air inside the equipment can be exhausted outside the equipment by using the heat exchange device, and the efficient heat exchange cycle and quick heat dissipation can be achieved.

To sum up, the heat exchange device and the equipment system using the same provided by the present disclosure are not anticipated by publications or used in public, which meets patentability of the invention. Examination of the present disclosure is respectfully requested, as well as allowance of the present disclosure.

The above-mentioned descriptions represent merely the exemplary embodiment of the present disclosure, without any intention to limit the scope of the present disclosure thereto. Various equivalent changes, alternations or modifications based on the claims of present disclosure are all consequently viewed as being embraced by the scope of the present disclosure.

What is claimed is:

1. A heat exchange device, comprising:
a pipe unit;
a vapor/gas pressurizer, connected to the pipe unit;
a heat dissipation device, connected to the vapor/gas pressurizer via the pipe unit;
a throttling device, connected to the heat dissipation device via the pipe unit;
a heat sink, connected to the throttling device and the vapor/gas pressurizer via the pipe unit, having a heat sinking surface;
a control unit, electrically connected and signaling to the vapor/gas pressurizer, the heat dissipation device, the throttling device and the heat sink; and
a case, wherein the vapor/gas pressurizer, the heat dissipation device, the throttling device and the control unit are disposed inside the case, and the heat sink is disposed outside the case.

2. The heat exchange device according to claim 1, wherein the heat dissipation device comprises a heat dissipation fin bank, a fan or a water cooling heat dissipation device.

3. The heat exchange device according to claim 1, wherein the throttling device is a capillary, a temperature-sensitive expansion valve, an electronic expansion valve or an oriface.

4. An equipment system having heat exchange ability, comprising:
an equipment and a heat exchange device;
wherein the heat exchange device comprises:
a pipe unit;
a vapor/gas pressurizer, connected to the pipe unit;
a heat dissipation device, connected to the vapor/gas pressurizer via the pipe unit;
a throttling device, connected to the heat dissipation device via the pipe unit;
heat sinks, wherein the heat sink is connected to the throttling device and the vapor/gas pressurizer via the pipe unit, and each of the heat sinks has a heat sinking surface; and
a control unit, electrically connected and signaling to the vapor/gas pressurizer, the heat dissipation device, the throttling device and the heat sink;
wherein working units are disposed inside the equipment, and the heat sinking surface contacts the working unit.

5. The equipment system according to claim 4, wherein the heat sinks are sequentially connected via the pipe unit.

6. The equipment system according to claim 4, wherein the working units have chips, each of the heat sinking surfaces contacts the corresponding chip, and the chip is a central processing unit or a graphics processing unit.

7. The equipment system according to claim 4, wherein the equipment further comprises a power supply disposed therein, the power supply is electrically connected to the working unit and the heat exchange device, the working unit further has a temperature sensor disposed between the heat sinking surface and the working unit, the temperature sensor contacts the heat sink and the working unit, the working unit further has a pulse width modulation gearing device, and the control unit is electrically connected and signaling to the pulse width modulation gearing device.

8. A heat exchange device, comprising:
pipe units;
a vapor/gas pressurizer, correspondingly connected to the pipe units;
a heat dissipation device, correspondingly connected to the vapor/gas pressurizer via the pipe unit;
a throttling device, correspondingly connected to the heat dissipation device via the pipe unit;
a heat sink, correspondingly connected to the throttling device and the vapor/gas pressurizer via the pipe units, wherein the heat sink has a heat sinking surface;
a control unit, electrically connected and signaling to the vapor/gas pressurizer, the heat dissipation device, the throttling device and the heat sink;
a heat conduction cycling box, comprising a box body, cooling liquid and an inner pipe disposed in the box body, and a cooling pipe, wherein the inner pipe and the cooling pipe are correspondingly connected to the heat sink via the pipe unit; and
a case, wherein the vapor/gas pressurizer, the heat dissipation device, the throttling device and the control unit are disposed inside the case, and the heat sink and the heat conduction cycling box are disposed outside the case.

9. The heat exchange device according to claim 8, wherein the heat dissipation device comprises a heat dissipation fin bank and a fan.

10. The heat exchange device according to claim 8, the throttling device is a capillary, a temperature-sensitive expansion valve, an electronic expansion valve or an oriface.

11. The heat exchange device according to claim 8, wherein the inner pipe is configured to have continuous U shape tubes.

12. The heat exchange device according to claim 8, wherein the heat conduction cycling box further has a drive part for driving operation of the heat conduction cycling box.

13. An equipment system having heat exchange ability, comprising:
a heat exchange device, comprising:
pipe units;
a vapor/gas pressurizer;
a heat dissipation device, correspondingly connected to the vapor/gas pressurizer via the pipe unit;
a throttling device, correspondingly connected to the heat dissipation device via the pipe unit;
heat sinks, correspondingly connected to the throttling device and the vapor/gas pressurizer via the pipe units, wherein each of the heat sinks has a heat sinking surface;
a control unit, electrically connected and signaling to the vapor/gas pressurizer, the heat dissipation device, the throttling device and the heat sink; and
a heat conduction cycling box, comprising a box body, cooling liquid and an inner pipe disposed in the box body, and a cooling pipe, wherein the inner pipe and the cooling pipe are correspondingly connected to the heat sink via the pipe unit; and
an equipment, wherein working units are disposed inside the equipment, and the heat sinking surfaces are correspondingly connected to the working units.

14. The equipment system according to claim 13, wherein the heat sinks are sequentially connected via the pipe units.

15. The equipment system according to claim 13, wherein the working units have chips, each of the heat sinking surfaces contacts the corresponding chip, and the chip is a central processing unit or a graphics processing unit.

16. The equipment system according to claim 15, wherein the equipment further comprises a power supply disposed therein, the power supply is electrically connected to the working unit and the heat exchange device, the working unit further has a temperature sensor disposed between the heat sinking surface and the working unit, the temperature sensor contacts the heat sink, the working unit further has a pulse width modulation gearing device, and the control unit is electrically connected and signaling to the pulse width modulation gearing device.

17. The equipment system according to claim 15, wherein a rated power of the central processing unit is more than or equal to 95 W, a rated power of the graphics processing unit is more than or equal to 150 W, and the heat exchange device is dedicated to dissipate heat of 250 W through 600 W.

18. A heat exchange device, comprising:
pipe units;
a vapor/gas pressurizer, correspondingly connected to the pipe units;
a heat dissipation device, correspondingly connected to the vapor/gas pressurizer via the pipe unit;
a throttling device, correspondingly connected to the heat dissipation device via the pipe unit;
a cooler, correspondingly connected to the throttling device and the vapor/gas pressurizer via the pipe units, wherein the cooler has an air blower;
a control unit, electrically connected and signaling to the vapor/gas pressurizer, the heat dissipation device, the throttling device and the cooler; and
a case, wherein the vapor/gas pressurizer, the heat dissipation device, the throttling device, the cooler and the control unit are disposed inside the case.

19. The heat exchange device according to claim 18, wherein the heat dissipation device comprises a heat dissipation fin bank and a fan.

20. The heat exchange device according to claim 18, wherein the heat dissipation device is a water cooling heat dissipation device.

21. The heat exchange device according to claim 18, wherein the throttling device is a capillary, a temperature-sensitive expansion valve, an electronic expansion valve or an oriface.

22. The heat exchange device according to claim 18, wherein the air blower is a fan, a clapboard is disposed between the vapor/gas pressurizer and the cooler, the case further has a first side plate, a second side plate being opposite to the first side plate and a third side plate covering and disposed on top portions of the first side plate and the second side plate.

23. An equipment system having heat exchange ability, comprising:
a heat exchange device, comprising:
pipe units;
a vapor/gas pressurizer;
a heat dissipation device, correspondingly connected to the vapor/gas pressurizer via the pipe unit;
a throttling device, correspondingly connected to the heat dissipation device via the pipe unit;
a cooler, correspondingly connected to the throttling device and the vapor/gas pressurizer via the pipe units, wherein the cooler has an air blower;
a control unit, electrically connected and signaling to the vapor/gas pressurizer, the heat dissipation device, the throttling device and the cooler; and
a case, wherein the vapor/gas pressurizer, the heat dissipation device, the throttling device, the cooler and the control unit are disposed inside the case; and
an equipment, having a housing, wherein a terminal portion of the housing has a side plate, and a through hole is disposed on the side plate, wherein the case is disposed on an inner top portion of the housing, such that the heat exchange device is installed in the through hole.

24. The equipment system according to claim 23, wherein the equipment further comprises a power supply disposed therein, the power supply is electrically connected to the heat exchange device, the equipment further has further comprises a power supply disposed therein, the power supply is electrically connected to the working unit and the heat exchange device further has a temperature sensor contacting the cooler, and the equipment further has a pulse width modulation gearing device, and the control unit is electrically connected and signaling to the pulse width modulation gearing device.
